(19) United States
(12) Patent Application Publication
(10) Pub. No.: US 2023/0298913 A1
(43) Pub. Date: Sep. 21, 2023

(54) BONDING APPARATUS AND A BONDING DEVICE THEREOF

(71) Applicant: All Ring Tech Co., Ltd., Kaohsiung City (TW)

(72) Inventors: Chun-Hung Tsai, Kaohsiung City (TW); An-Tien Wang, Kaohsiung City (TW); Kuan-Lin Cheng, Kaohsiung City (TW); Shih-Min Lee, Kaohsiung City (TW)

(21) Appl. No.: 18/152,071

(22) Filed: Jan. 9, 2023

(30) Foreign Application Priority Data
Mar. 18, 2022 (TW) 111110121

(51) Int. Cl. H01L 21/67; H01L 21/677; B32B 37/12; H01L 21/683

(52) U.S. Cl. CPC H01L 21/67132; H01L 21/67763; B32B 37/1207; H01L 21/6836; B32B 2457/14; H01L 2221/68318; H01L 2221/6834

(57) ABSTRACT

A bonding apparatus for attaching an adhering pad to a base component includes a feeding and holding frame for feeding and holding the base component in a conveying route, a suspending carrier mounted above the conveying route, and a bonding device disposed on and movable with the suspending carrier. The bonding device has a feeding reel on which the tape assembly is disposed and from which the tape assembly is pulled and fed along a feeding route, and an attaching head which is disposed at said feeding route to divide the pulled section into an input side and an output side. When the attaching head is moved toward the input side, the adhering pad is removed from the carrier tape while attached to the base component.

### CROSS-REFERENCE TO RELATED APPLICATION

This application claims priority to Taiwanese Patent Application No. 111110121, filed on Mar. 18, 2022.

### FIELD

The disclosure relates to a bonding apparatus and a bonding device thereof, and more particularly to a bonding apparatus for attaching an adhering pad to a base component in an automatic manufacturing process.

### BACKGROUND

In a conventional IC packaging process, adhesive is applied on a substrate, a die is attached to the substrate, a layer of thermal conductive glue is applied over the die, and then a heat sink is attached to cover the die and the substrate. To simplify the glue coating process, the thermal conductive glue has been replaced by a thermal conductive pad with adhesives on both sides thereof and two cover films removably covering the surface of both sides. In use, the operator peels off one cover film on the bottom-surface side of the thermal conductive pad to attach the bottom-surface side to an upper-surface of a die, and then peels off the other cover film on the top-surface side of the thermal conductive pad to permit a heat sink to be attached to the top-surface side. However, such process of manually adhering each thermal conductive pad is inefficient in mass production, and results in poor quality products.

A bonding method and a bonding apparatus have been developed for attaching a thermal conductive pad to an upper surface of a die on a substrate in an automatic manufacturing process, such as the method and the apparatus disclosed in Taiwanese Invention Patent No. 716906. A round-shaft shaped attaching head is driven to roll and to be moved over a carrier tape on which a thermal conductive pad is adhered, to attach the thermal conductive pad to a base component. Thereafter, the attaching head is driven to return back to its original position to remove the carrier tape from the thermal conductive pad. This results in two rolling strokes of the attaching head which is an inefficient process.

### SUMMARY

Therefore, an object of the disclosure is to provide a bonding apparatus and a bonding device thereof that can alleviate at least one of the drawbacks of the prior art.

According to the disclosure, the bonding device is for attaching an adhering pad to a base component. A plurality of the adhering pads are peelably attached and arranged to a flexible carrier tape and are covered by a cover tape to form a tape assembly. The bonding device includes a transporting mechanism and a bonding mechanism mounted on the transporting mechanism to perform attachment of the adhering pad to an upper surface of the base component. The bonding mechanism has a feeding reel on which the tape assembly is disposed and from which a pulled section of the tape assembly is pulled and fed along a feeding route, and an attaching head which is disposed at the feeding route to divide the pulled section into an input side and an output side. When the attaching head is operated to move toward the input side of the tape assembly, one side of the adhering pad is removed from the carrier tape while the other side of the adhering pad is attached to the upper surface of the base component.

According to the disclosure, the bonding apparatus includes a feeding and holding frame which has a conveying route extending in an X-direction for feeding and holding the base component, a transferring rail mechanism which has a suspending carrier mounted above the conveying route and movable in a Y-direction, and the bonding device which is disposed on and movable with the suspending carrier, and which is operable to move relative to the suspending carrier in the X-direction to perform attachment of the adhering pad to an upper surface of the base component.

### BRIEF DESCRIPTION OF THE DRAWINGS

Other features and advantages of the disclosure will become apparent in the following detailed description of the embodiments with reference to the accompanying drawings. It is noted that various features may not be drawn to scale.

FIG. 1 is a schematic view of a chip package structure.

FIG. 2 is a schematic view of a base component and a thermal conductive pad.

FIG. 3 is a schematic view of a tape assembly.

FIG. 4 is a perspective view illustrating an embodiment of a bonding apparatus according to the disclosure.

FIG. 5 is a schematic view illustrating a fixture and its operating mechanism of the embodiment.

FIG. 6 is an exploded perspective view of a bonding device of the embodiment.

FIG. 7 is an exploded perspective view of a transporting mechanism of the bonding device.

FIG. 8 is a perspective view illustrating a bonding mechanism of the bonding device.

FIG. 9 is a perspective view illustrating the bonding device taken from another angle.

FIG. 10 is a fragmentary perspective view illustrating the bonding mechanism.

FIG. 11 is a perspective view illustrating the bonding device with a tape assembly mounted/installed thereon.

FIG. 12 is a schematic front view illustrating the bonding device with the tape assembly mounted/installed thereon.

FIG. 13 is a schematic view illustrating an input route and an output route of the tape assembly.

FIG. 14 is a schematic view illustrating a shift lever operated to press the tape assembly.

FIG. 15 is a fragmentary perspective view illustrating a guide wheel of the bonding device of another embodiment.

FIG. 16 is a fragmentary perspective view illustrating the bonding mechanism of the embodiment in FIG. 15.

FIG. 17 is a perspective view illustrating still another embodiment of a bonding apparatus according to the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

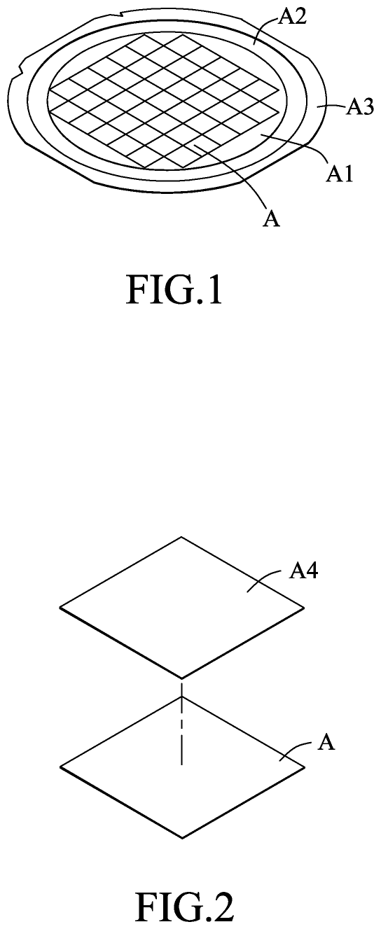

Referring to FIG. 1, an embodiment of a bonding apparatus is adapted to perform pad attachment of a base component (A). The base component (A) may be a die on a wafer (A1). The wafer (A1) is disposed on a film (A2) having a surrounding frame (A3) that surrounds the wafer (A1). The wafer (A1) is cut into a plurality of base components (A) in a matrix arrangement. The base components (A) lie separately on a horizontal plane. In the pad attachment process, as shown in FIG. 2, an adhering pad (A4), such as a thermal conductive pad, is attached to an upper surface of each base component (A).

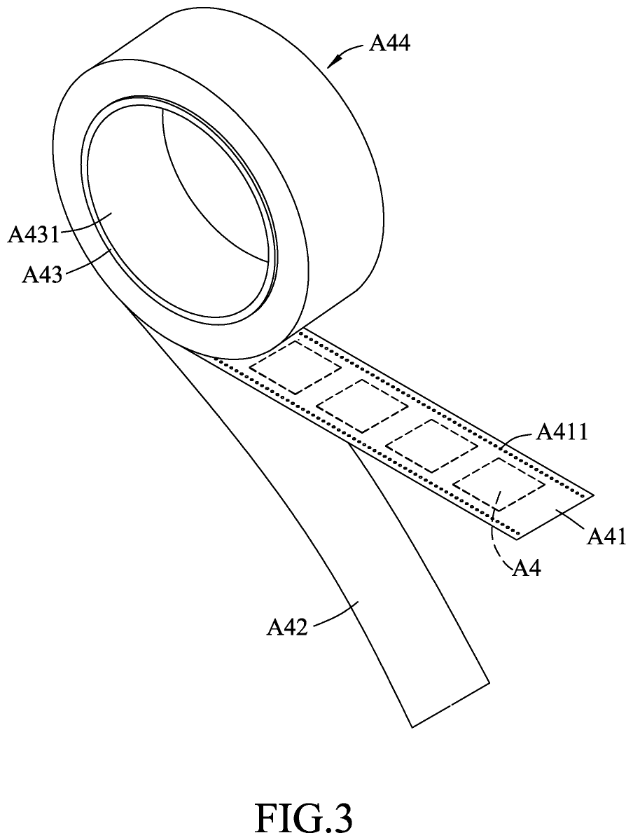

Referring to FIG. 3, in one embodiment, a plurality of the adhering pads (A4) are peelably attached and arranged to a flexible carrier tape (A41) and are covered by a cover tape (A42). The carrier tape (A41) and the cover tape (A42) cooperatively enclose the adhering pads (A4), and the adhering pads (A4) are spaced apart from one another and arranged in a lengthwise direction of the carrier tape (A41). The adhering pads (A4) are double sided and, the two sides of each adhering pad (A4) are peelably adhered on the carrier tape (A41) and the cover tape (A42), respectively. Two rows of pin holes (A411) are formed in the carrier tape (A41) adjacent to two long edges thereof and spaced apart from each other by a distance that is larger than the width of the adhering pads (A4). The adhering pads (A4) are disposed between the two rows of the pin holes (A411). The carrier tape (A41) is reeled on a sleeve (A43) with an axial hole (A431) to form a tape assembly (A44).

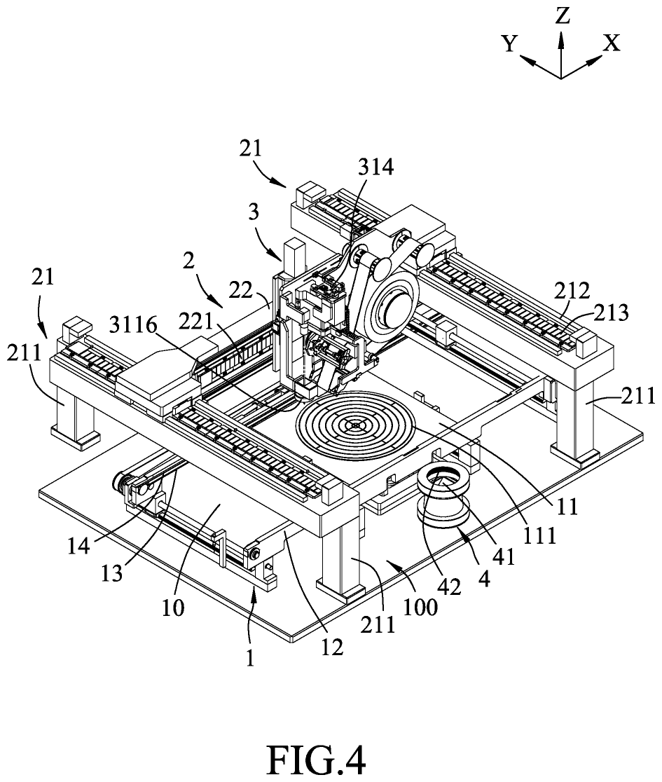

With reference to FIG. 4, the bonding apparatus of one embodiment includes a machine base 100, a feeding and holding frame 1 which has a conveying route 10 extending in an X-direction for feeding and holding the base component (A), a transferring rail mechanism 2 which has a suspending carrier 22 mounted above the conveying route 10 and movable in a Y-direction, a bonding device 3 and a lower detecting unit 4.

The feeding and holding frame 1 has a fixture 11. The fixture 11 has a plurality of upper attractive portions 111 which are concentrically arranged annular grooves and from which a negative air pressure is provided. The feeding and holding frame 1 includes two lateral frames 12 spaced apart from each other in the Y-direction, and two belts 13 respectively disposed on the lateral frames 12 to cooperatively define two rails 14. The conveying route 10 is formed between the rails 14, and is operable for conveying the film (A2) having the surrounding frame (A3) and the wafer (A1) (as shown in FIG. 1) in the X-direction to feed the film (A2) upon the fixture 11. The film (A2) is held by the upper attractive portions 111 of the fixture 11 and is moved with the fixture 11 in a Z-direction.

The transferring rail mechanism 2 includes two gantry cranes 21 spaced apart from each other in the X-direction and disposed across the conveying route 10. Each gantry crane 21 includes two support legs 211 disposed at two sides of the conveying route 10 and extending in the Z-direction, and a suspending beam 212 extending in the Y-direction and disposed on the tops of the support legs 211. A Y-axis driver 213, such as a linear motor, is disposed on the suspending beam 212. The suspending carrier 22 extends in the X-direction and is disposed on the suspending beams 212. Two ends of the suspending carrier 22 are respectively driven by the Y-axis drivers 213 to move in the Y-direction relative to the suspending beams 212. An X-axis driver 221, such as a linear motor, is disposed on the suspending carrier 22.

The bonding device 3 is disposed on and movable with the suspending carrier 22 and above the feeding and holding frame 1. The bonding device 3 is also driven by the X-axis driver 221 to move relative to the suspending carrier 22 in the X-direction to perform attachment of the adhering pad (A4).

The lower detecting unit 4 includes an image sensor 41 with a CCD lens which captures images upwardly, and a light source 42 disposed adjacently to the image sensor 41.

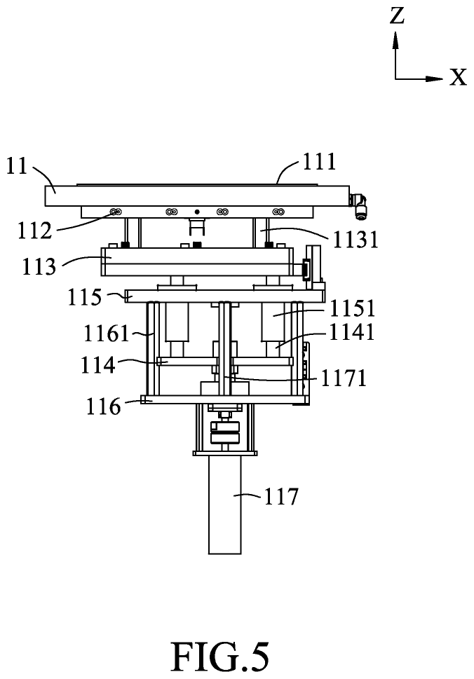

With reference to FIGS. 4 and 5, the fixture 11 has a heating element 112 indirectly heating the base component (A) (see FIG. 1) held on the attractive portions 111. A base seat 113 has a plurality of upright spacers 1131 on which the fixture 11 is disposed, and is supported on and movable via a plurality of pivot shafts 1141 of a moving element 114 which is disposed under the machine base 100. A positioning element 115 is disposed on the machine base 100, and has a plurality of pivot sleeves 1151 in which the pivot shafts 1141 are respectively and movably inserted. The positioning element 115 is securely connected with a positioning seat 116 by a plurality of support elements 1161. A driver 117, such as a motor, is disposed under the positioning seat 116, and provides a torque which rotates a screw shaft 1171 and moves the moving element 114 in the Z-direction so as to move the base seat 113 and the fixture 11.

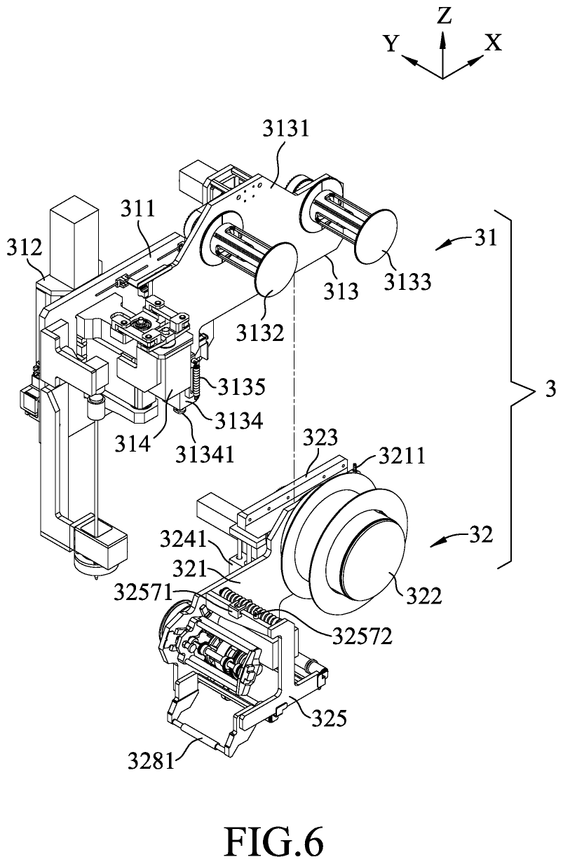

With reference to FIG. 6, the bonding device 3 includes a transporting mechanism 31 and a bonding mechanism 32 disposed on the transporting mechanism 31 to move with the transporting mechanism 31 for performing the attachment process of the adhering pad (A4).

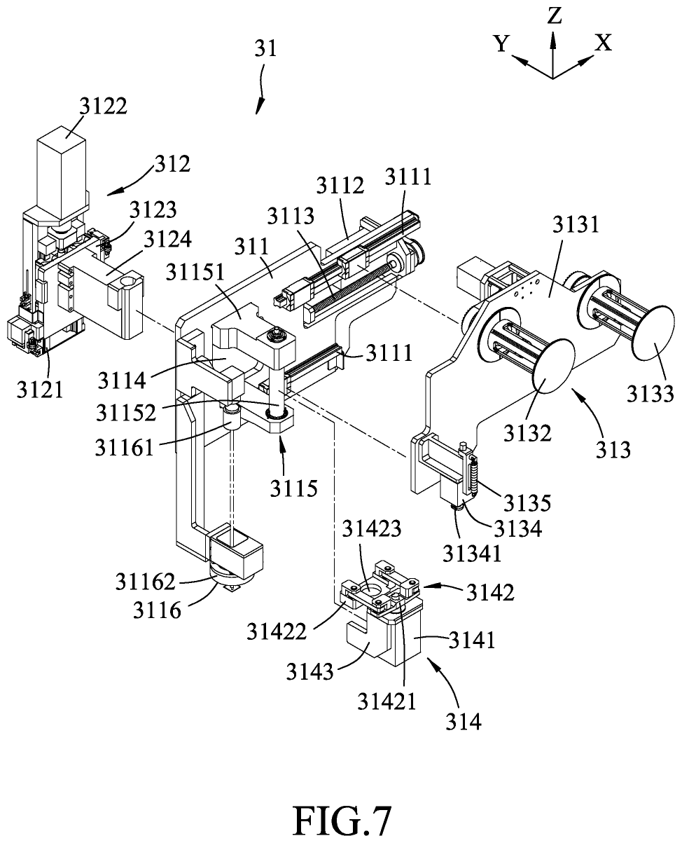

With reference to FIGS. 6 and 7, the transporting mechanism 31 includes a plate-like transporting upright seat 311, an upright rail seat 312 on which the transporting upright seat 311 is movably mounted in the Z-direction, a reeling assembly 313 which is mounted on and operably movable relative to the transporting upright seat 311 in the X-direction, and a deflection correcting assembly 314 which is disposed on the transporting upright seat 311 and which drives deflection of the transporting upright seat 311 relative to the upright rail seat 312.

The transporting upright seat 311 has two sliding rails 3111 spaced apart from each other in the Z-direction and extending in the X-direction, and a screw bolt 3113 disposed between the sliding rails 3111 and driven by a driver 3112. The transporting upright seat 311 has a through operating space 3114 and a support bracket 3115 disposed at a side of the through operating space 3114. The support bracket 3115 includes two pivot lugs 31151 which project from the transporting upright seat 311 respectively at upper and lower sides of the through operating space 3114, and a pivot shaft 31152 which extends in the Z-direction to couple with the two pivot lugs 31151. The transporting upright seat 311 further has an upper detecting unit 3116. The upper detecting unit 3116 has an image sensor 31161 with a CCD lens which captures images downwardly, and a light source 31162 disposed under the image sensor 31161.

The upright rail seat 312 is disposed on the suspending carrier 22 of the transferring rail mechanism 2, and has two sliding rails 3121 which extend in the Z-direction, and a sliding seat 3123 which is driven by a driving motor 3122 to move along the sliding rails 3121. The sliding seat 3123 has a projecting seat 3124 through which the pivot shaft 31152 is pivotably mounted, and which extends in the Y-direction through the through operating space 3114 of the transporting upright seat 311 such that the transporting upright seat 311 is carried by the projecting seat 3124 and moved therewith in the Z-direction.

The reeling assembly 313 includes a plate-like reeling upright seat 3131 which is mounted on and slidable along the sliding rails 3111 of the transporting upright seat 311 to be moved with the screw bolt 3113 in the X-direction, a first reel 3132 which is rotatably mounted on the reeling upright seat 3131 for reeling the carrier tape (A41) (see FIG. 3) that the cover tape (A42) and the adhering pad (A4) are peeled from, and a second reel 3133 which is rotatably mounted on the reeling upright seat 3131 for reeling the cover tape (A42) that is peeled from the carrier tape (A41). In addition, the reeling assembly 313 has a driver 3134 in the form of a pneumatic cylinder actuated in the Z-direction, and a resilient member 3135 in the form of a biasing spring.

The deflection correcting assembly 314 includes a driving motor 3141 and a linkage mechanism 3142 in the form of a four-bar linkage and is driven by the driving motor 3141. A fixed bar 31421 is coupled with an output end of the driving motor 3141, and a movable bar 31422 is disposed parallel to the fixed bar 31421 and has an axial hole 31423 for extension of the pivot shaft 31152 in the Z-direction. Two retaining members 3143 are disposed at two sides of the driving motor 3141 in the X-direction, and are respectively and secured on two sides of the projecting seat 3124 of the upright rail seat 312 so as to move the deflection correcting assembly 314 with the projecting seat 3124.

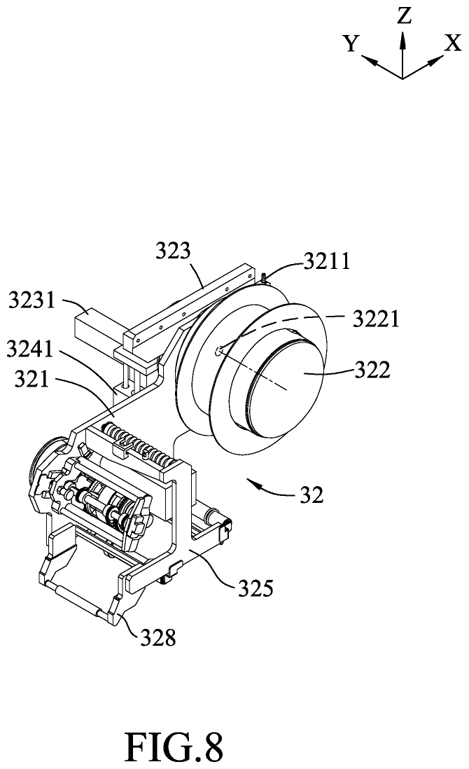

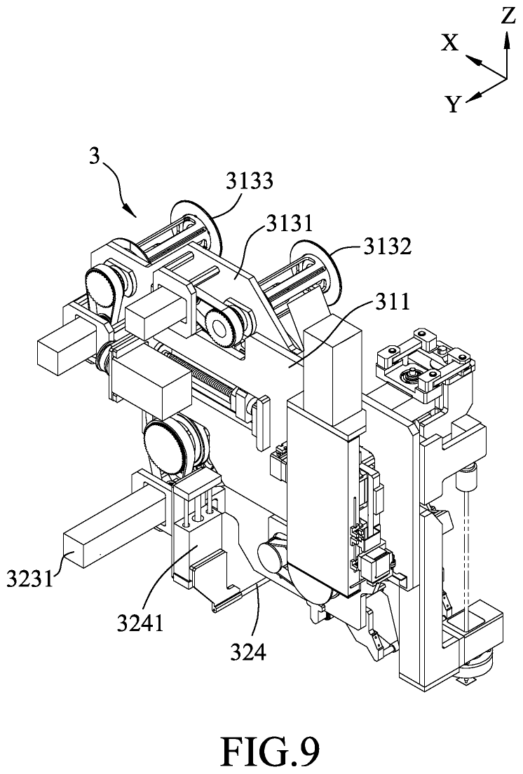

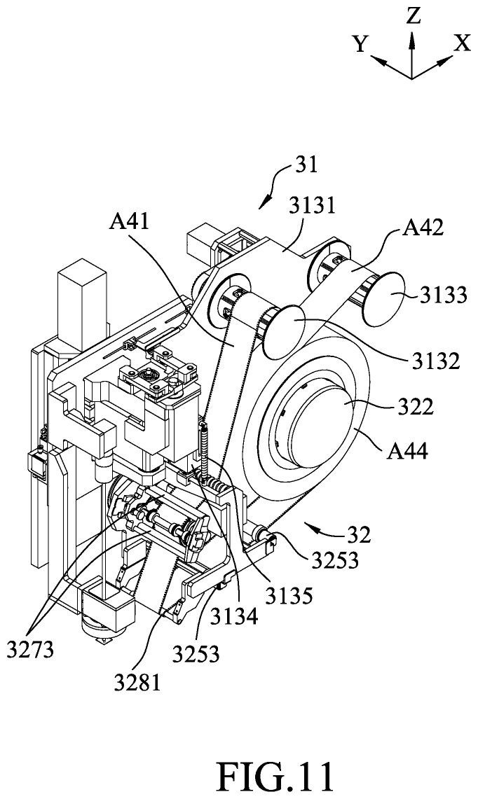

With reference to FIGS. 8 and 9, the bonding mechanism 32 includes a plate-like bonding upright seat 321, a feeding reel 322 which is pivotably mounted at a side of the bonding upright seat 321, and a positioning seat 323 which is mounted at the other side of the bonding upright seat 321. The tape assembly (A44) is disposed on the feeding reel 322 (see FIG. 11) and a pulled section of the tape assembly (A44) is pulled from the feeding reel 322 to be fed along a feeding route. The feeding reel 322 has a reel axle 3221 which rotatably extends through the bonding upright seat 321 in the Y-direction and which is mounted to the positioning seat 323. The reel axle 3221 is driven to rotate intermittently by a driver 3231 (such as a motor) which is mounted at a side of the positioning seat 323. Also, the positioning seat 323 is securely mounted on a lower portion of the reeling upright seat 3131 of the reeling assembly 313 (see FIG. 7) to permit the bonding mechanism 32 to be moved with the reeling assembly 313 in the X-direction. In addition, the bonding upright seat 321 is swingable about a pivot axis of the reel axle 3221 relative to the positioning seat 323 and the reeling upright seat 3131 (see FIG. 7) while the first and second reels 3132, 3133 are kept unmoved relative to the feeding reel 322. Further, the bonding mechanism 32 includes a shift lever 324 at a lower portion of the bonding upright seat 321 (as shown in FIG. 9). The shift lever 324 extends from the bonding upright seat 321 in the Y-direction away from the feeding reel 322. The shift lever 324 is driven by a driver 3241 (such as a pneumatic cylinder) which is disposed at the side of the bonding upright seat 321 away from the feeding reel 322 to be moved in a Z-direction relative to the bonding upright seat 321. Further, a fine adjusting member 3211 is disposed at a side of the bonding upright seat 321 adjacent to the feeding reel 322, and has an upright externally threaded portion. The bonding mechanism 32 further includes a carrier bracket 325 which is disposed on the same side of the bonding upright seat 321 as the feeding reel 322.

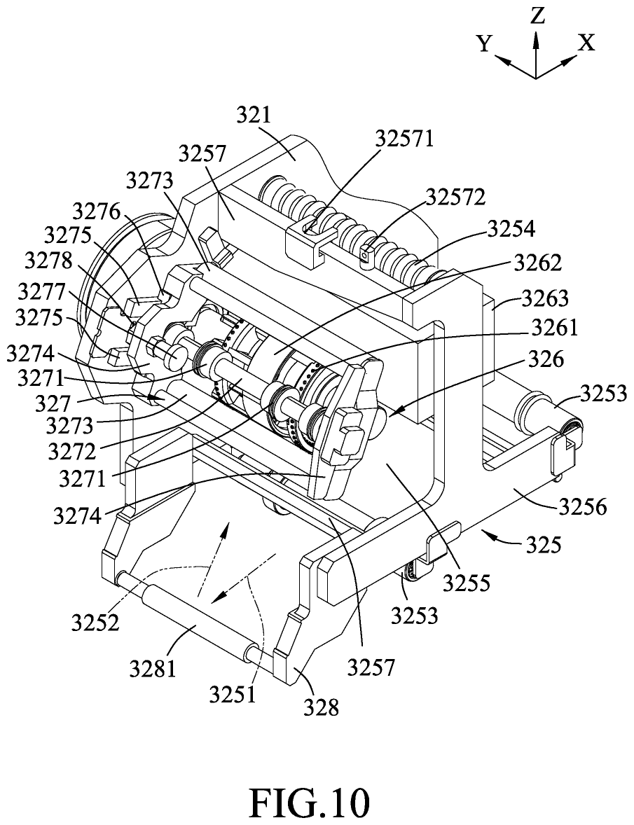

With reference to FIG. 10, the carrier bracket 325 is configured to define thereon a lower input route 3251 of the pulled section of the tape assembly (A44) and an upper output route 3252 of the pulled section of the tape assembly (A44). Specifically, a plurality of converting rollers 3253 are mounted at the lower input route 3251, and a converting roller 3254 is mounted at the upper output route 3252. A guide wheel 326 is disposed on the bonding upright seat 321 at the upper output route 3252 and extends in the Y-direction. The guide wheel 326 has two surrounding pin portions 3261 at two end surfaces thereof, and a rolling portion 3262 disposed between the surrounding pin portions 3261. The guide wheel 326 is driven to rotate intermittently by a driving motor 3263. A tape pressing bracket 327 is disposed adjacent to the guide wheel 326. The tape pressing bracket 327 is rectangular, and has a central shaft 3272 extending in the Y-direction, two wheel sleeves 3271 sleeved on two end portions of the central shaft 3272 and respectively aligned with the surrounding pin portions 3261, and two pressing shafts 3273 disposed at two sides of the central shaft 3272 and extending in the Y-direction. Two couplers 3274 are disposed on two ends of the central shaft 3272. One coupler 3274 which is proximate to the bonding upright seat 321 is secured to a slider 3276 which is slidable along two sliding rails 3275 on the bonding upright seat 321 such that the tape pressing bracket 327 is operable to slide radially close to or away from the guide wheel 326. A lock pin 3277 is disposed on an inner side of the coupler 3274, and is resiliently insertable into a lock hole 3278 formed in the bonding upright seat 321 between the sliding rails 3275 so as to restrain the tape pressing bracket 327 to be close to the guide wheel 326.

The carrier bracket 325 includes a lateral mount 3256 which is spaced apart from the bonding upright seat 321 by a feeding space 3255, and a plurality of crosspieces 3257 which are disposed between the lateral mount 3256 and the bonding upright seat 321. The converting rollers 3253 are also disposed between the lateral mount 3256 and the bonding upright seat 321. An uppermost crosspiece 3257 has first and second connecting members 32571, 32572, to which a lower end of a cylinder piston 31341 of the driver 3134 and a lower end of the resilient member 3135 (as shown in FIG. 7) are respectively connected, that couples the bonding mechanism 32 with the reeling assembly 313 so as to move the bonding mechanism 32 in response to the movement of the reeling assembly 313 in the Z-direction. Further, the bonding mechanism 32 includes a mounting bracket 328 disposed at an end of the carrier bracket 325 distal from the feeding reel 322 (see FIG. 8). An attaching head 3281 is in the form of a round shaft extending in the Y-direction and is mounted on the mounting bracket 328. The attaching head 3281 is disposed at the feeding route in the feeding space 3255, and at a junction of the lower input route 3251 and the upper output route 3252. The lower input route 3251 and the upper input route 3252 intersect each other at an included angle which is an acute angle, i.e., less than 90 degrees.

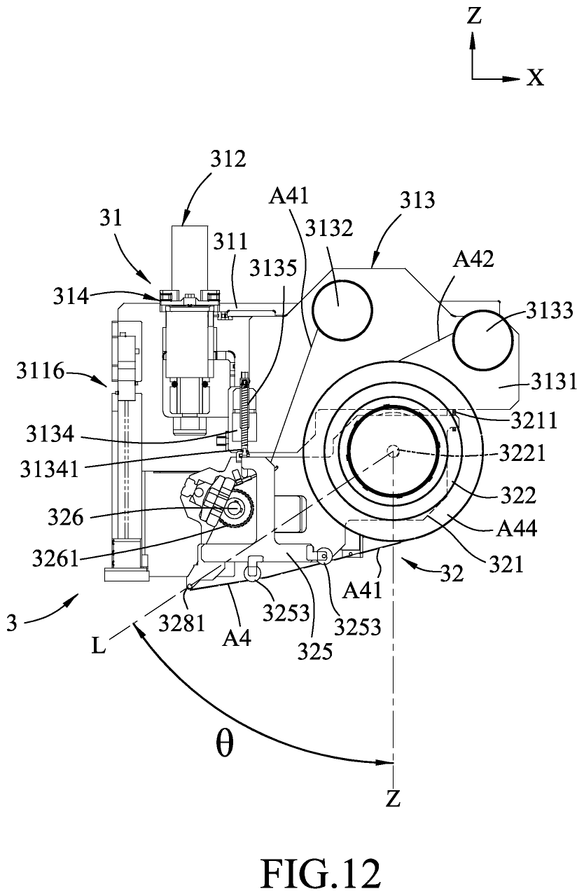

With reference to FIGS. 11, 12 and 13, the bonding upright seat 321 of the bonding mechanism 32 is swingable about the pivot axis of the reel axle 3221. In a normal state, the attaching head 3281 is disposed at, in a clockwise direction, a left side of an upright line (Z) extending through the reel axle 3221 and in the Z-direction, as shown in FIG. 12. A line (L) extending through the attaching head 3281 and the reel axle 3221 intersects the upright line (Z) at an included angle (0) which is between 45 degrees and 90 degrees. The cylinder piston 31341 of the driver 3134 is spaced apart from the reel axle 3221 and operable to press the bonding mechanism 32 downward so as to apply a first torque to the attaching head 3281 in a counterclockwise direction with respect to the reel axle 3221, and bring the fine adjusting member 3211 to abut against a lower edge of the reeling upright seat 3131. At this stage, the attaching head 3281 is placed at a downward working position 3282 in the clockwise direction with respect to the reel axle 3221. Meanwhile, the resilient member 3135 in the form of a biasing spring supports a portion of the weight of the bonding mechanism 32. That is, the resilient member 3135 applies a second torque to the attaching head 3281 in the clockwise direction with respect to the reel axle 3221. The first torque is opposite to the second torque. The displacement of the attaching head 3281 caused by the first torque determines a height of the working position, which is adjustable by the fine adjusting member 3211.

When the tape assembly (A44) is reeled on the feeding reel 322, the cover tape (A42) is peeled from the carrier tape (A41) and is reeled on the second reel 3133. The carrier tape (A41) is fed, with the adhering pad (A4) facing downward, along the lower input route 3251 through the converting rollers 3253 and the attaching head 3281, and then along the upper output route 3252 through the surrounding pin portions 3261 of the guide wheel 326, and is reeled on the first reel 3132. The pressing shafts 3273 are operable to press and abut against the carrier tape (A41) passing on the guide wheel 326, as shown in FIG. 11.

With reference to FIGS. 4, 12 and 13, in an attaching process, the upper detecting unit 3116 is operated to capture a downwardly image of the base component (A), and the bonding device 3 is then moved adjacent to the lower detecting unit 4 such that the lower detecting unit 4 upwardly detects the adhering pad (A4) on the underside of the carrier tape (A41). In an image capturing process of the adhering pad (A4), as shown in FIG. 14, the shift lever 324, which is disposed between the feeding reel 322 and the attaching head 3281, is operated to press the pulled section of the carrier tape (A41) so as to move the lower input route 3251 downwardly to shift the pulled section of the carrier tape (A41) at the input side from an inclined state to a horizontal state (as indicated by dotted lines). Thus, a precise orientation of the adhering pad (A4) can be detected by the lower detecting unit 4. Subsequently, the shift lever 324 is operated to move upwardly and return back its original position and the carrier tape (A41) is returned to the inclined state (it is noted that, for certain types of adhering pads, the carrier tape (A41) may be held in a horizontal state). In case of a deflection existing between the orientations of the base component (A) and the adhering pad (A4) detected by the upper detecting unit 3116 and the lower detecting unit 4, the deflection correcting assembly 314 is operated to angularly and horizontally move the transporting upright seat 311 relative to the upright rail seat 312 so as to deflect the attaching head 3281 to correct the orientation of the adhering pad (A4) and permit it corresponding with the base component (A).

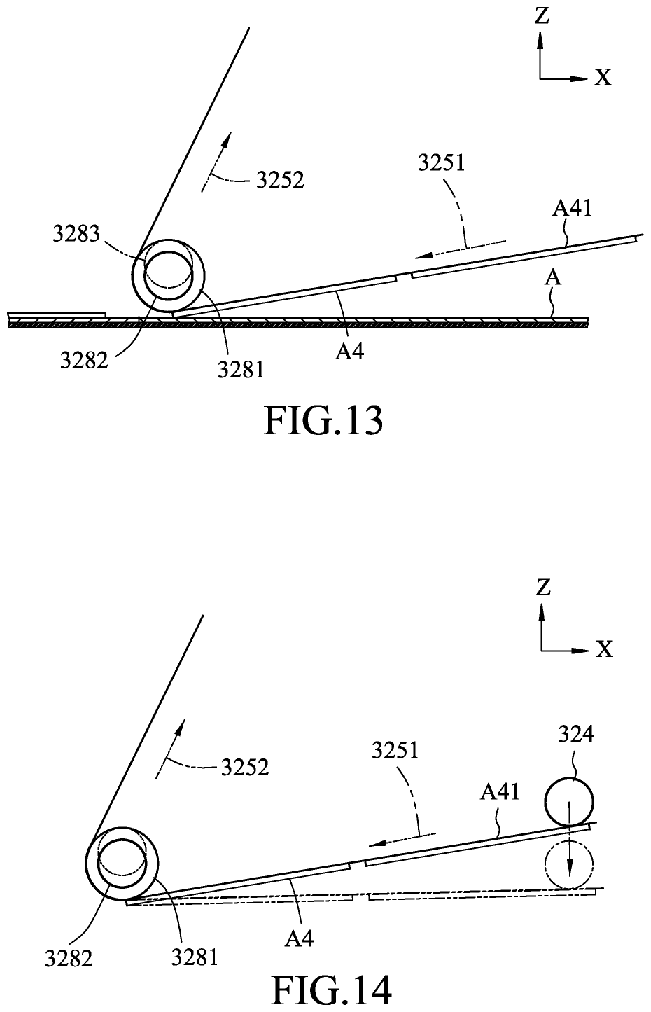

Subsequently, with reference to FIGS. 12 and 13, the upright rail seat 312 is operated to drive the transporting upright seat 311 to move downwardly and to move the reeling assembly 313 and the bonding mechanism 32 downwardly to a predetermined position above the base component (A). At this stage, one side of the adhering pad (A4) is aligned with and abutted by the attaching head 3281 which is at the working position. An upward counteracting force generating as a result of downward movement of the attaching head 3281 in the Z-direction to press the carrier tape (A41) and the adhering pad (A4) upon the base component (A) can cause a slight raising of the cylinder piston 31341 of the driver 3134 to provide damping to the downward pressure, and bring the attaching head 3281 to turn (i.e., angularly movable about the pivot axis of the reel axle 3221) upwardly in the clockwise direction to an attaching position 3283. At this stage, the fine adjusting member 3211 is spaced apart from the reeling upright seat 3131. Thus, the pulled section of the carrier tape (A41) passes through the attaching head 3281 and is divided by the attaching head 3281 into an input side at the lower input route 3251, and an output side at the upper output route 3252.

The feeding movement of the carrier tape (A41) at the lower input route 3251 stops, and the reeling upright seat 3131 of the reeling assembly 313 is operated to move along the sliding rails 3111 (see FIG. 7) in the X-direction to move the first reel 3132, the second reel 3133 and the bonding mechanism 32 in the X-direction. The attaching head 3281 is moved and rolls over the carrier tape (A41) in the X-direction to indirectly press the adhering pad (A4) under the carrier tape (A41) so as to rollably move from a side near the upper output route 3252 toward the other side of the lower input route 3251. At this stage, the guide wheel 326 and the first reel 3132 are operated to reel the carrier tape (A41) and the adhering pad (A4) is carried by the carrier tape (A41) to the underside of the attaching head 3281. Thus, during the feeding movement of the carrier tape (A41) from the lower input route 3251 to the upper output route 3252, one side of the adhering pad (A4) is removed from the carrier tape (A41) while the other side of the adhering pad (A4) is attached downward to the upper surface of the base component (A).

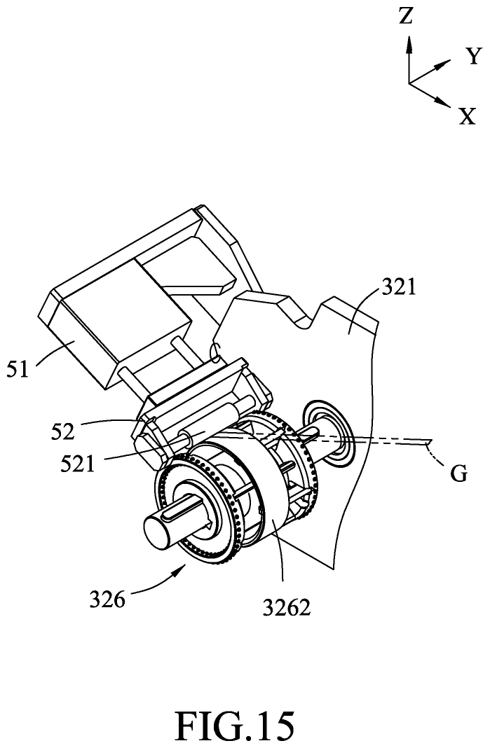

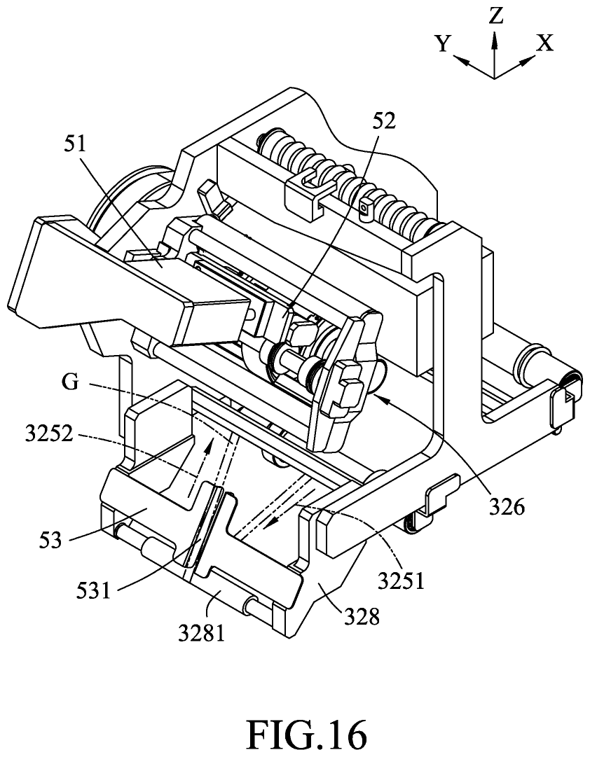

With reference to FIGS. 15 and 16, in a modified embodiment, the bonding apparatus is used with a tape assembly which has a specific carrier tape (G) and adhering pads. For example, the carrier tape is narrow in width without the pinholes. A driver 51 is in the form of a pneumatic cylinder, and is disposed on the bonding upright seat 321 and adjacent to the guide wheel 326. A tape pressing member 52 has a pressing roller 521 which is driven by the driver 51 to press and abut against the carrier tape (G) which passes through the rolling portion 3262. A stabilizing member 53 is disposed on the mounting bracket 328 at the upper output route 3252, and has a duct 531 for passage of the carrier tape (G) which is fed from the lower input route 3251, through the underside of the attaching head 3281 and the duct 531, to the upper output route 3252.

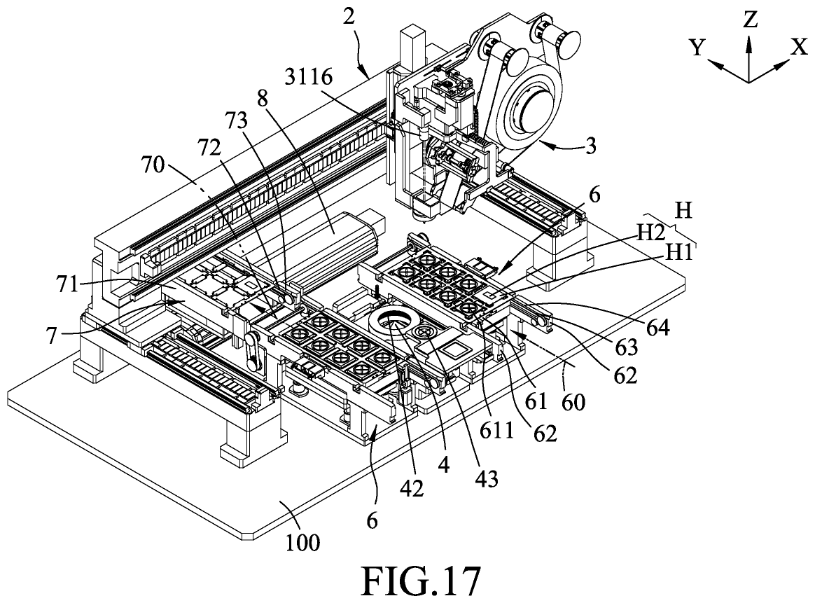

With reference to FIG. 17, in another embodiment, the bonding apparatus is for attaching an adhering pad to a die (H2) on a substrate (H1). The bonding apparatus also includes the transferring rail mechanism 2 and the bonding device 3 similar to those in the previous embodiment as shown in FIG. 4. The bonding apparatus includes two feeding and holding frames 6 which are disposed on a machine base 100 and spaced apart from each other in the X-direction. Each feeding and holding frame 6 has a fixture 61. The fixture 61 has a plurality of rectangular upper attractive portions 611 that each provide a negative air pressure. Each feeding and holding frame 6 includes two lateral frames 62 spaced apart from each other in the X-direction, and two belts 63 respectively disposed on the lateral frames 62 to cooperatively define two rails 64. A conveying route 60 is formed between the rails 64 and extends in the Y-direction. The conveying route 60 is operable for conveying the base component (H) having dies (H2) attached to a substrate (H1) to feed the base component (H) upon the fixture 61. The base component (H) is held by the upper attractive portion 611 of the fixture 61 and is moved with the fixture 61 in the Z-direction. A movable rail bracket 7 is disposed at ends of the two feeding and holding frames 6, and is movable on and along an X-direction rail seat 8 in the X-direction. The movable rail bracket 7 includes two lateral frames 71 spaced apart from each other in the X-direction, and two belts 72 respectively disposed on the lateral frames 71 to cooperatively define two rails 73. A conveying route 70 is formed between the rails 73 and extends in the Y-direction. The movable rail bracket 7 is movable to align the conveying route 70 with the conveying route 60 of a selective one of the feeding and holding frames 6. The lower detecting unit 4 is disposed between the conveying routes 60 of the feeding and holding frames 6, and has a movable aligning seat 43 which is selectively moved above the light source 42 for facilitating alignment of the upper detecting unit 3116 with the lower detecting unit 4.

As illustrated, with the attaching head 3281 which is disposed at the feeding route to divide the pulled section of the carrier tape (A41) into the input side and the output side. The attaching head 3281 is angularly moved about the pivot axis of the reel axle 3221 of the feeding reel 322 to the working position 3282. The adhering pad (A4) is removed from the carrier tape (A41) and is attached to the base component (A). Thus, in the feeding movement of the carrier tape (A41), by means of the attaching head 3281, the adhering pad (A4) is removed from the carrier tape (A41) while attached to the base component (A) synchronously without the need to roll and reciprocate the attaching head 3281 so as to increase the bonding efficiency.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A bonding device for attaching an adhering pad to a base component, wherein a plurality of the adhering pads are peelably attached and arranged to a flexible carrier tape and are covered by a cover tape to form a tape assembly, comprising:
a transporting mechanism; and
a bonding mechanism mounted on said transporting mechanism to perform attachment of the adhering pad to an upper surface of the base component, said bonding mechanism having a feeding reel on which the tape assembly is disposed and from which a pulled section of the tape assembly is pulled and fed along a feeding route, and an attaching head which is disposed at said feeding route to divide the pulled section into an input side and an output side, wherein, when said attaching head is operated to move toward the input side of the tape assembly, one surface side of the adhering pad is removed from the carrier tape while the other surface side of the adhering pad is attached to the upper surface of the base component.

2. The bonding device as claimed in claim 1, wherein said bonding mechanism includes a bonding upright seat, said feeding reel being mounted at a side of said bonding upright seat, and having a reel axle which rotatably extends through said bonding upright seat in a Y-direction, which is mounted to a positioning seat that is mounted at the other side of said bonding upright seat, and which is driven to rotate intermittently by a driver that is mounted at a side of said positioning seat, said transporting mechanism including a reeling assembly which has a reeling upright seat, said positioning seat being securely mounted on said reeling upright seat to permit said bonding mechanism to be moved with said reeling upright seat.

3. The bonding device as claimed in claim 1, wherein said transporting mechanism includes a transporting upright seat and a reeling assembly which is mounted on and operably movable relative to said transporting upright seat, said reeling assembly having a reeling upright seat, a first reel which is rotatably mounted on said reeling upright seat for reeling the carrier tape from that the cover tape and the adhering pad are peeled, and a second reel which is rotatably mounted on said reeling upright seat for reeling the cover tape that is peeled from the carrier tape,
said bonding mechanism includes a bonding upright seat on which said feeding reel is pivotably mounted, said bonding upright seat being disposed to be movable relative to said reeling upright seat and keep said first and second reels unmoved relative to said feeding reel.

4. The bonding device as claimed in claim 3, wherein said reeling assembly has a driver and/or a resilient member which is/are coupled with said bonding mechanism to move said bonding mechanism in response to movement of said reeling assembly in a Z-direction.

5. The bonding device as claimed in claim 1, wherein said bonding mechanism has a shift lever which is disposed between said feeding reel and said attaching head and which is operable by a driver to be moved in a Z-direction to press the pulled section of the tape assembly so as to shift the pulled section at the input side from an inclined state to a horizontal state.

6. The bonding device as claimed in claim 1, wherein said attaching head is disposed to be angularly movable about a pivot axis of said reel axle such that said attaching head is angularly moved from a working position to an attaching position when said attaching head is moved in a Z-direction to press upon the base component.

7. The bonding device as claimed in claim 1, wherein said attaching head is disposed to be subject to a first torque and a second torque about a pivot axis which are opposite to each other, wherein a rotational movement of said attaching head caused by the first torque being adjustable.

8. The bonding device as claimed in claim 1, wherein said attaching head is in form of a round shaft and is disposed at a junction of a lower input route of the pulled section of the tape assembly and an upper output route of the pulled section of the tape assembly, the lower input route and the upper input route intersecting each other at an included angle which is an acute angle that is less than 90 degrees, a line extending through said attaching head and said reel axle intersecting an upright line extending through said reel axle and in a Z-axis direction at an included angle which is between 45 degrees and 90 degrees.

9. A bonding apparatus for attaching an adhering pad to a base component, wherein a plurality of the adhering pads are peelably attached and arranged to a flexible carrier tape and are covered by a cover tape to form as a tape assembly, comprising:
a feeding and holding frame which has a conveying route extending in an X-direction for feeding and holding the base component;
a transferring rail mechanism which has a suspending carrier mounted above said conveying route and movable in a Y-direction; and
a bonding device which is disposed on and movable with said suspending carrier, and which is operable to move relative to said suspending carrier in the X-direction to perform attachment of the adhering pad to an upper surface of the base component, said bonding device having a feeding reel on which the tape assembly is disposed and from which a pulled section of the tape assembly is pull and fed along a feeding route, and an attaching head which is disposed at said feeding route to divide the pulled section into an input side and an output side, wherein, when said attaching head is operated to move toward the input side of the tape assembly, one side of the adhering pad is removed from the carrier tape while the other side of the adhering pad is attached to the upper surface of the base component.
